(19) United States
(12) Patent Application Publication
(10) Pub. No.: US 2021/0215735 A1
(43) Pub. Date: Jul. 15, 2021

(54) THREE-AXIS ACCELEROMETER

(71) Applicant: MiraMEMS Sensing Technology Co., Ltd, Suzhou Industrial Park (CN)

(72) Inventors: Li-Tien TSENG, Taoyuan City (TW); Yu-Hao CHIEN, Taipei City (TW)

(21) Appl. No.: 17/217,416

(22) Filed: Mar. 30, 2021

Related U.S. Application Data
(63) Continuation-in-part of application No. 16/361,771, filed on Mar. 22, 2019.

(30) Foreign Application Priority Data
Dec. 5, 2018 (CN) 201811479157.1

(51) Int. Cl. G01P 15/18; G01P 15/125; G01P 1/00

(52) U.S. Cl. CPC G01P 15/18; G01P 2015/0871; G01P 1/00; G01P 15/125

(57) ABSTRACT

A three-axis accelerometer measures acceleration in three axes by a single movable mass block, so that a more compact design of the three-axis accelerometer can be achieved. In addition, a plurality of detection capacitors, which forms differential capacitor pairs, are arranged in symmetric configuration with respect to a rotation axis of the movable mass block for sensing functions. Therefore, during sensing motion of a target axis direction, the all other unwanted capacitance changes in other axis direction may be cancelled.

### CROSS-REFERENCE TO RELATED APPLICATIONS

This is a Continuation-in-Part application of U.S. patent application Ser. No. 16/361,771, filed Mar. 22, 2019 which claims benefit of China Patent Application No. 201811479157.1 filed Dec. 5, 2018, the disclosure of which is hereby incorporated by references.

### BACKGROUND OF THE INVENTION

### 1. Field of the Invention

The present invention relates to an accelerometer, particularly to a MEMS-based three-axis accelerometer.

### 2. Description of the Prior Art

Since the concept of the microelectromechanical system (MEMS) emerged in 1970s, MEMS devices have evolved from the targets explored in laboratories into the objects integrated with high-level systems. Nowadays, MEMS-based devices have been extensively used in consumer electronics, and the application thereof is still growing stably and fast. A MEMS-based device includes a mobile MEMS component. The function of a MEMS-based device may be realized through measuring the physical magnitude of the movement of the MEMS component.

Accelerometers have been extensively used in consumer electronics, automotive electronics, IoT (Internet of Things) devices, and other fields of engineering, science or industry. In the conventional three-axis accelerometers, multiple independent mass elements are used to sense accelerations in different axial directions. Thus, the conventional three-axis accelerometers are normally bulky, complicated in structure, and hard to fabricate.

Accordingly, providing a compact-structured three-axis accelerometer has been a target the manufacturers are eager to achieve.

### SUMMARY OF THE INVENTION

A three-axis accelerometer is provided herein, which uses a single movable mass block to measure the accelerations in three axial directions and is characterized in a compact structure.

A three-axis accelerometer is provided in which the variation of the difference of two differential capacitor pairs of an arbitrary axis is almost equal to zero while movements take place in other axes, whereby interference to the other axes is reduced.

A three-axis accelerometer is provided in which the positions of an anchor point and a conductive contact that is fixed to a fixed electrode are concentrated on the geometric center, so as to decrease residual stress-induced output signal drift occurring in the succeeding processes such as the package process and the soldering process.

A three-axis accelerometer includes a first substrate and a second substrate. The first substrate includes a metal layer, wherein a portion of the metal layer is exposed from a surface of the first substrate to form a circuit pattern, wherein the surface is parallel to a two-dimensional plane defined by a first axis and a second axis, and a third axis is vertical to the surface, the first axis and the second axis. The second substrate in form of a frame structure is deposited on the first substrate, which includes a movable mass block connected with the first substrate through an anchor point and an elastic element, and the movable mass block is able to move along the first axis parallel to the surface, rotate with respect to the third axis, and swing with respect to the second axis. The movable mass block includes at least two third-axis movable electrode regions respectively disposed at two portions on two sides of the second axis, and the two third-axis movable electrode regions form two third-axis sensing capacitors corresponding to the circuit pattern. The two third-axis sensing capacitors form a third-axis differential capacitor pair for detecting the displacement of the movable mass block in the third axis direction. The second substrate further includes plural first-axis movable electrode elements and plural second-axis movable electrode elements connected to the interior of the frame structure. The plural first-axis stator electrode elements are electrically connected with the circuit pattern and disposed corresponding to the plural first-axis movable electrode elements. The plural first-axis stator electrode elements and the plural first-axis movable electrode elements form plural first-axis sensing capacitors which include two first-axis parts with increasing capacitances and two first-axis parts with decreasing capacitances when used to sense in the first axis direction due to capacitor gaps change. For performing sensing function, the two first-axis parts with increasing capacitances are rotational symmetric to the third axis and allocated in a first diagonal relationship with respect to the anchor point, and the two first-axis parts with decreasing capacitance are rotational symmetric to the third axis and allocated in a second diagonal relationship with respect to the anchor point, and the first diagonal and the second diagonal are crossing. The plural second-axis stator electrode elements are electrically connected with the circuit pattern and disposed corresponding to the plural second-axis movable electrode elements, and the plural second-axis stator electrode elements and the plural second-axis movable electrode elements form plural second-axis sensing capacitors. The plural second-axis sensing capacitors include two second-axis parts with increasing capacitances and two second-axis parts with decreasing capacitances when used to sense in the second axis direction due to capacitor gaps change. For performing sensing function, the two second-axis parts with increasing capacitances are rotational symmetric to the third axis and allocated in a third diagonal relationship with respect to the anchor point, and the two second-axis parts with decreasing capacitance are rotational symmetric to the third axis and allocated in a fourth diagonal relationship with respect to the anchor point, and the third diagonal and the fourth diagonal are crossing at the anchor point 23.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1 is a front view schematically showing a portion of elements of a three-axis accelerometer according to a first embodiment of the present invention.

FIG. 2 is a sectional view taken along Line 00 in FIG. 1 and schematically showing the elements and structures along Line 00 according to the first embodiment of the present invention.

FIG. 3 is a diagram schematically showing a portion of elements of a three-axis accelerometer according to a second embodiment of the present invention.

FIG. 4 is a diagram schematically showing a portion of elements of a three-axis accelerometer according to a third embodiment of the present invention.

FIG. 5 is a diagram schematically showing a portion of elements of a three-axis accelerometer according to a fourth embodiment of the present invention.

FIG. 6 is a diagram schematically showing a portion of elements of a three-axis accelerometer according to a fifth embodiment of the present invention.

FIG. 7 is a diagram schematically showing a 2-dimensional plane of a movable mass block, which is defined by a first axis and a second axis according to one embodiment of the present invention.

FIG. 8 is a diagram schematically showing variation of thicknesses of a movable mass block along a third axis according to one embodiment of the present invention.

FIG. 9 is a top-view diagram of X-Y(A1-A2) plane illustrating the movable mass block 20a of sixth example according to the present invention.

FIG. 10 is a schematic diagram illustrating position variation of movable X-axis sensing comb parts when exemplary movable mass block rotates clockwise during sensing acceleration rate of Y axis according to the present invention.

FIG. 11 is a capacitance table illustrating measured capacitances in three different sensing directions as target axes performed by the three-axis accelerometer including one in FIG. 9.

FIG. 12 is a top-view diagram of X-Y(A1-A2) planes respectively illustrating the movable mass block 20a of seventh example according to the present invention.

FIG. 13 is a top-view diagrams of X-Y(A1-A2) planes respectively illustrating the movable mass block 20a of eighth example according to the present invention.

FIG. 14 is a top-view diagrams of X-Y(A1-A2) planes respectively illustrating the movable mass block 20a of nineth example according to the present invention.

### DESCRIPTION OF THE PREFERRED EMBODIMENTS

The present invention will be described in detail with embodiments and attached drawings below. However, these embodiments are only to exemplify the present invention but not to limit the scope of the present invention. In addition to the embodiments described in the specification, the present invention also applies to other embodiments. Further, any modification, variation, or substitution, which can be easily made by the persons skilled in that art according to the embodiment of the present invention, is to be also included within the scope of the present invention, which is based on the claims stated below. Although many special details are provided herein to make the readers more fully understand the present invention, the present invention can still be practiced under a condition that these special details are partially or completely omitted. Besides, the elements or steps, which are well known by the persons skilled in the art, are not described herein lest the present invention be limited unnecessarily. Similar or identical elements are denoted with similar or identical symbols in the drawings. It should be noted: the drawings are only to depict the present invention schematically but not to show the real dimensions or quantities of the present invention. Besides, matter less details are not necessarily depicted in the drawings to achieve conciseness of the drawings.

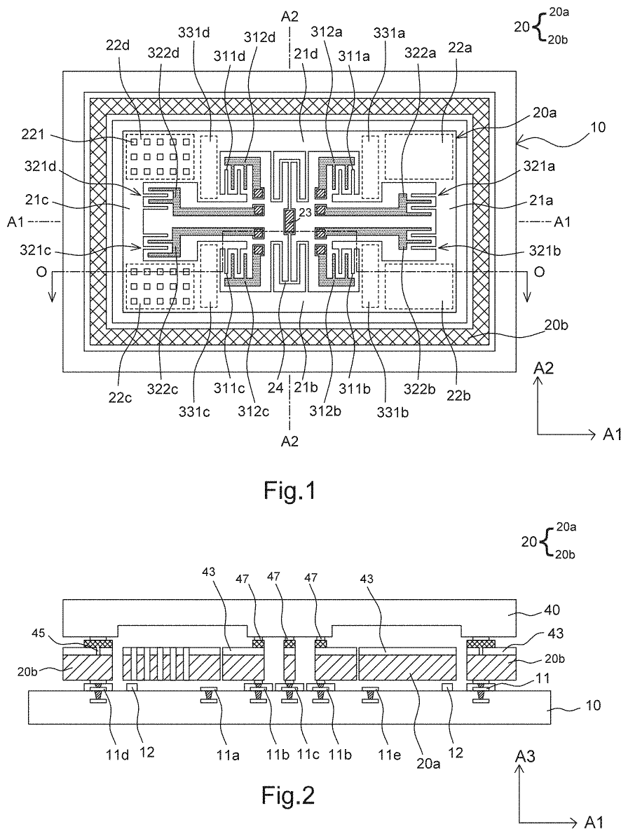

Refer to FIG. 1 and FIG. 2. In one embodiment, the three-axis accelerometer of the present invention includes a first substrate 10, a movable mass block 20a, four first-axis stator electrode elements 312a, 312b, 312c, and 312d, and four second-axis stator electrode elements 322a, 322b, 322c, and 322d. In one embodiment, the three-axis accelerometer of the present invention further includes a cover 40. The cover 40 and the first substrate 10 jointly form a receiving room. The cover 40 and the first substrate 10 also jointly secure the stator electrodes of the moveable mass block 20a. The movable mass block 20a is disposed inside the receiving room between the first substrate 10 and the cover 40. The first substrate 10 includes a metal layer 11. A portion of the metal layer 11 is exposed on a surface of the first substrate 10 to form a circuit pattern. For example, the exposed circuit pattern may function as a third-axis stator electrode 11a and a third-axis stator electrode 11e, function as electric-conduction contacts 11b electrically connected with the first-axis stator electrode elements 312a, 312b, 312c, and 312d, and the second-axis stator electrode elements 322a, 322b, 322c, and 322d, function as an electric-conduction contact 11c electrically connected with the movable mass block 20a, or function as an electric-conduction contact 11d electrically connected with the cover 40. The circuit pattern includes a complementary metal-oxide-semiconductor (CMOS) element. In other words, the first substrate 10 is a substrate for CMOS. In one embodiment, the first substrate 10 is a silicon substrate. A second substrate 20, which is disposed above the first substrate 10, includes the movable mass block 20a and an annular stator structure 20b. Besides, the cover 40 uses a plurality of fixing contacts 47 to insulatingly fix the anchor point 23 of the movable mass block 20a, a plurality of stator electrode elements of each axis, and the annular stator structure 20b surrounding the movable mass block 20a. The cover 40, the annular stator structure 20b, and the first substrate 10 may form an airtight chamber to protect the sensing elements disposed thereinside. Further, a dielectric layer 43 is formed on the movable mass block 20a, the upper surface of the annular stator structure 20b, and the fixing contacts 47 beforehand; next, an electric-conduction layer is formed on a portion of the dielectric layer 43; then, the dielectric layer 43 is perforated to form electric-conduction contacts 45, whereby to form the electric connection of the cover 40 and the first substrate 10. While the cover 40 and the movable mass block 20a are bonded, the formation and selective perforation of the dielectric layer 43 may simultaneously insulatingly secure the fixing contacts 47 and the anchor point 23 and provide a special potential for the cover 40.

The movable mass block 20a is in form of a frame structure. For example, the movable mass block 20a includes a plurality of connection segments 21a, 21b, 21c and 21d and a plurality of mass regions 22a, 22b, 22c and 22d, which are connected to form a rectangular frame structure. In the embodiment shown in FIG. 1, the plurality of mass regions 22a-22d is disposed at four ends of the long axes of the frame structure (first axes A1). However, the present invention is not limited by this embodiment. In one embodiment, the mass regions are disposed in the edges of the short axes of the frame structure (second axes A2). The movable mass block 20a is connected with the first substrate 10 through at least one anchor point 23 and at least one elastic element 24, whereby the movable mass block 20a can move along the direction of the first axis A1 on the surface of the first substrate 10 (the surface defined by the first axis A1 and the second axis A2) and can swing with respect to the second axis A2, which is parallel to the surface of the first substrate 10 and vertical to the first axis A1. Thus, the movable mass block acts like a seesaw. Further, the movable mass block 20a rotates with respect to the third axis A3 which is protruded from and vertical to the surface of the first substrate 10. In the embodiment shown in FIG. 1, the third axis A3 passes through the anchor point 23 and is vertical to the first axis A1 and the second axis A2. In other words, the third axis A3 protrudes from the plane defined by the first axis A1 and the second Axis A2. In one embodiment, the movable mass block 20a is a piece of monocrystalline silicon or a piece of doped low-resistance silicon.

In one embodiment, the connection area of the anchor point 23 and the first substrate 10 includes an alloy, which includes at least one selected from a group including aluminum, copper, germanium, indium, gold, and silicon. The connection area may further include an electric-conduction material, which has sufficient rigidity to maintain the connection interface. In one embodiment, a low-resistance ohmic contact is formed between the connection area and the first substrate 10. In one embodiment, the connection area includes germanium, aluminum or copper. In other embodiments, the connection area may include other materials, such as gold, indium, and solder materials for wetting and modifying the metal stack and for bonding the bottom. For example, the cover 40, the movable mass block 20a, the annular stator structure 20b, the first-axis stator electrode elements 312a-312d, and the second-axis stator electrode elements 322a-322d may be respectively a substrate and may respectively bond with the first substrate 10 in form of a substrate through at least one of the technologies of fusion bond, eutectic bond, conductive eutectic bond, and adhesiveness. In one embodiment, the connection interface is compressed and heated to enable the reflow reaction of the electric-conduction material in the connection interface. The bonding structure generated by the reflow reaction of the electric-conduction material can provide the ohmic contact between the first substrate 10 and the movable mass block 20a, the first-axis stator electrode elements 312a-312d, and the second-axis stator electrode elements 322a-322d. It is preferred: an electric-conduction eutectic bonding is formed between the first substrate 10 and the movable mass block 20a, the first-axis stator electrode elements 312a-312d, and the second-axis stator electrode elements 322a-322d, whereby extra electric-conduction paths do not need be used between the first substrate 10 and the movable mass block 20a. In one embodiment, the bonding can be realized via eutectic bonding technology. For example, Au—In, Cu—Sn, Au—Ge, Al—Ge, Al—Si, Au—Si.

In the embodiment shown in FIG. 1, the anchor point 23 is disposed in the interior of the frame structure, and the elastic element 24 is also connected to the interior of the frame structure. The regions of the movable mass block 20a distributed on two sides of the second axes A2 may have different masses so as to form an appropriate difference of rotation inertia. Thus, the sensitivity of the accelerometer may raise because the movable mass block 20a is easy to swing with respect to the second axis A2, just like a seesaw. For example, the formation of through-holes 221 within the mass regions on one side of the second axis A2, such as the mass regions 22c and 22d, may reduce the masses of the mass regions 22c and 22d. Alternatively, the thicknesses of the mass regions 22c and 22d are decreased to make the thicknesses of the mass regions 22c and 22d smaller than the thicknesses of the mass regions 22a and 22b, whereby difference exists between the masses of the mass regions on two sides of the second axis A2.

Refer to FIG. 1 and FIG. 2. The movable mass block 20a further includes four third-axis movable electrode regions 331a, 331b, 331c and 331d which are respectively disposed on two sides of the first axes A1. For example, the third-axis movable electrode regions 331a and 331d are disposed on the same side of the first axes A1, preferably symmetrically disposed with respect to the second axis A2; the third-axis movable electrode regions 331b and 331c are disposed on the other side of the first axes A1, preferably symmetrically disposed with respect to the second axis A2. The four third-axis movable electrode regions 331a-331d cooperate with the plurality of third-axis stator electrodes 11a and third-axis stator electrodes 11e on the surface of the first substrate 10 to form four third-axis sensing capacitors. The set of third-axis sensing capacitor which is formed by third-axis movable electrode region 331a and the third-axis stator electrodes 11e, and the set of third-axis sensing capacitor which is formed by third-axis movable electrode region 331d and the third-axis stator electrodes 11a, may jointly form a third-axis differential capacitor pair for detecting the displacement of the movable mass block 20a in the third axis direction. The third-axis sensing capacitor which is formed by third-axis movable electrode region 331b and the third-axis stator electrodes 11e, and the third-axis sensing capacitor which is formed by third-axis movable electrode region 331c and the third-axis stator electrodes 11a, may jointly form another third-axis differential capacitor pair for detecting the displacement of the movable mass block 20a in the third axis direction. In such a structure, while the movable mass block 20a rotates/swings with respect to the second axis A2, in any one of the third-axis differential capacitor pair, the capacitance of one third-axis sensing capacitor will increase a capacitance difference, and the capacitor of the other third-axis sensing capacitor will decrease the same capacitance difference so as to acquire the double capacitance difference. Similarly, another third-axis differential capacitor pair also acquires double the capacitance difference. Therefore, the three-axis accelerometer of the present invention can acquire four times the capacitance difference in total. Thus, the accuracy of detecting acceleration in the third-axis A3 is increased. In one embodiment, a stop bump 12 is disposed on a position of the surface of the first substrate 10, which is corresponding to the movable mass block 20a, whereby to decrease the contact area of the movable mass block 20a and the first substrate 10, and whereby to prevent the movable mass block 20a from failing by the adhesion between the movable mass block 20a and the first substrate 10.

Refer to FIG. 1 and FIG. 2 again. The movable mass block 20a also includes four first-axis movable electrode elements 311a, 311b, 311c, and 311d and four second-axis movable electrode elements 321a, 321b, 321c and 321d. In one embodiment, the first-axis movable electrode elements 311a-311d and the second-axis movable electrode elements 321a-321d are all connected to the interior of the frame structure of the movable mass block 20a, wherein the first-axis movable electrode elements 311a-311d are symmetrically disposed with respect to the third axis A3, and wherein the second-axis movable electrode elements 321a-321d are also symmetrically disposed with respect to the third axis A3. The first-axis stator electrode elements 312a-312d are electrically connected with the electric-conduction contacts 11b of the first substrate 10 and corresponding to the first-axis movable electrode elements 311a-311d to form four first-axis sensing electrode capacitors, respectively. The four first-axis sensing electrode capacitors are symmetrically disposed with respect to the third axis A3 to form two first-axis differential capacitor pairs. For example, the sets of the first-axis sensing capacitors which are formed by the first-axis movable electrode elements 311a and 311c and the first-axis stator electrode elements 312a and 312c, jointly form a first-axis differential capacitor pair; the sets of the first-axis sensing capacitors which are formed by the first-axis movable electrode elements 311b and 311d and the first-axis stator electrode elements 312b and 312d, jointly form another first-axis differential capacitor pair. In such a structure, while the three-axis accelerometer shifts towards the positive direction of the first axis A1, the movable mass block 20a moves towards left side shown in FIG. 1, in the direction of the first axis A1 due to inertial force, in one first-axis differential capacitor pair, the capacitance of the sensing capacitor formed by the first-axis movable electrode element 311a and the first-axis stator electrode element 312a will increase by a capacitance difference, and the capacitance of the other sensing capacitor formed by the first-axis movable electrode element 311c and the first-axis stator electrode element 312c will decrease by a capacitance difference, so as to acquire the double capacitance difference through the differential circuit. Similarly, in the other first-axis differential capacitor pair, the capacitance of the sensing capacitor formed by the first-axis movable electrode element 311b and the first-axis stator electrode element 312b will increase by a capacitance difference, and the capacitance of the sensing capacitor formed by the first-axis movable electrode element 311d and the first-axis stator electrode element 312d may decrease by a capacitance difference, so as to acquire the double capacitance difference through the differential circuit. Therefore, the three-axis accelerometer of the present invention can acquire four times the capacitance difference totally. Thus, the accuracy of detecting acceleration in the first axis A1 is increased.

Refer to FIG. 1 and FIG. 2 again. The plurality of first-axis capacitor pairs and the plurality of second-axis capacitor pairs are disposed around the anchor point 23 with the anchor point 23 being the center. In other words, the first-axis capacitor pairs and the second-axis capacitor pairs are designed to be disposed in the periphery of the electric-conduction contacts 11c, which are electrically connected with the anchor point 23. The eight capacitor pairs and the anchor point 23 are all distributed around the geometrical center of the three-axis accelerometer, whereby to reduce the affection of the distortion and stress caused by the succeeding SMT (Surface Mount Technology) process.

Refer to FIG. 1 and FIG. 2 again. The second-axis stator electrode elements 322a-322d are electrically connected with the electric-conduction contacts 11b of the first substrate 10 and disposed corresponding to the second-axis movable electrode elements 321a-321d to form four second-axis sensing capacitors. Similarly, the second-axis sensing capacitors disposed symmetrically with respect to the rotation axis (the third axis A3 passing through the anchor point) respectively form a second-axis differential capacitor pair. For example, the sets of second-axis sensing capacitors formed by the second-axis movable electrode elements 321a and 321c and the second-axis stator electrode elements 322a and 322c, form a second-axis differential capacitor pair; the sets of second-axis sensing capacitors formed by the second-axis movable electrode elements 321b and 321d and the second-axis stator electrode elements 322b and 322d, form another second-axis differential capacitor pair. In such a structure, when the three-axis accelerometer is moved in the positive direction of the second axis A2 and the movable mass block 20a rotates clockwise with the third axis A3 being the rotation axis due to the inertial force, in one second-axis differential capacitor pair, the capacitance of the sensing capacitor formed by the second-axis movable electrode element 321a and the second-axis stator electrode element 322a, increases by a capacitance difference; the capacitance of the sensing capacitor formed by the second-axis movable electrode element 321c and the second-axis stator electrode element 322c, decreases by a capacitance difference. Thus, double the capacitance difference is acquired through the differential circuit. In the other second-axis differential capacitor pair, the capacitance of the sensing capacitor formed by the second-axis movable electrode element 321d and the second-axis stator electrode element 322d, increases by a capacitance difference; the capacitance of the sensing capacitor formed by the second-axis movable electrode element 321b and the second-axis stator electrode element 322b, decreases by a capacitance difference. Thus, double the capacitance difference is acquired through the differential circuit. Therefore, the three-axis accelerometer of the present invention can acquire four times the capacitance difference totally. Thus, the accuracy of detecting acceleration in the second axis A2 is increased. In one embodiment, each of the first-axis movable electrode elements 311a-311d, the first-axis stator electrode elements 312a-312d, the second-axis movable electrode elements 321a-321d, and the second-axis stator electrode elements 322a-322d is a finger electrode.

As mentioned above, the movable mass block 20a may move parallel along the first axis A1 to detect the acceleration in the first axis A1, rotate with respect to the third axis A3 protruding from the plane to detect the acceleration in the second axis A2; further, the movable mass block 20a may rotate/swing with respect to the second axis A2 (i.e. the anchor point 23) to detect the acceleration in the third axis A3. Refer to FIG. 1 and FIG. 2 again. While the movable mass block 20a rotates/swings with respect to the second axis A2, the third-axis movable electrode regions 331a and 331b of the two third-axis differential capacitor pairs of the movable mass block 20a move in the same direction, and the third-axis two third-axis movable electrode regions 331c and 331d of the two third-axis differential capacitor pairs also move in the same direction. In other words, while the three-axis accelerometer experiences the acceleration in the third axis direction, the different mass distributions of the movable mass block 20a on two sides of the second axis A2 cause the movable mass block 20a to rotate/swing, whereby the third-axis movable electrode regions 331a and 331b simultaneously move toward or far away from the third-axis stator electrodes 11e, and whereby the third-axis movable electrode regions 331c and 331d simultaneously move toward or far away from the third-axis stator electrodes 11a. Therefore, the capacitance of one third-axis sensing capacitor of any third-axis differential capacitor pair will increase by a capacitance difference, and the capacitance of the other third-axis sensing capacitor corresponding to the same third-axis differential capacitor pair will decrease by a capacitance difference. Thus, double the capacitance difference is acquired. Similarly, another third-axis differential capacitor pair also acquires double the capacitance difference. Hence, the three-axis accelerometer of the present invention acquires four times the capacitance difference totally. Then is increased the accuracy of detecting the acceleration in the third axis.

According to the structure shown in FIG. 1, the first-axis movable electrode elements 311a, 311c or 311b, 311d, and the second-axis movable electrode elements 321a, 321c or 321b, 321d of the first axis differential capacitor pair and the second-axis differential capacitor pair are symmetrically disposed on two sides of the rotation axis. For example, while the acceleration is detected in the direction of the first axis A1, the second-axis movable electrode elements 321c and 321d respectively approach the second-axis stator electrode elements 322c and 322d, whereby the capacitance is increased. At the same time, the second-axis movable electrode elements 321a and 321b respectively move far away from the second-axis stator electrode elements 322a and 322b, whereby the capacitance is decreased. Thus, the capacitance variation in the two differential capacitor pairs approaches zero. In the meanwhile, the detection electrode plate of the third axis A3 (the third-axis movable electrode regions and the third-axis stator electrodes) is insensitive to the motion of the movable mass block 20a in the direction of the second axis A2. While the acceleration is detected in the direction of the second axis A2, the movable mass block 20a rotates clockwise or counterclockwise with the third axis A3 being the rotation axis. At the same time, the first-axis movable electrode elements 311b and 311d respectively close to or far away from the first-axis stator electrode elements 312b and 312d, in the meanwhile, the first-axis movable electrode elements 311a and 311c respectively move far away from or close to the first-axis stator electrode elements 312a and 312c. Thus, the total capacitance variation from both differential capacitor pairs are also approaches zero.

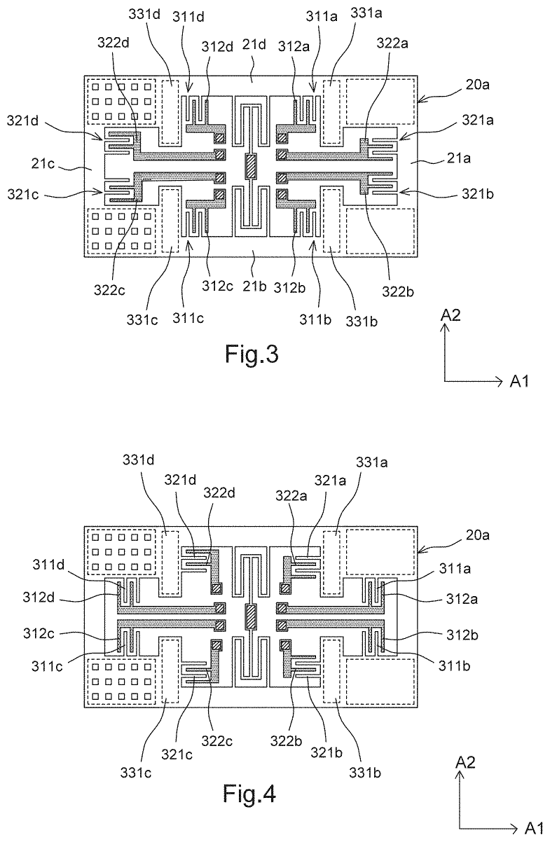

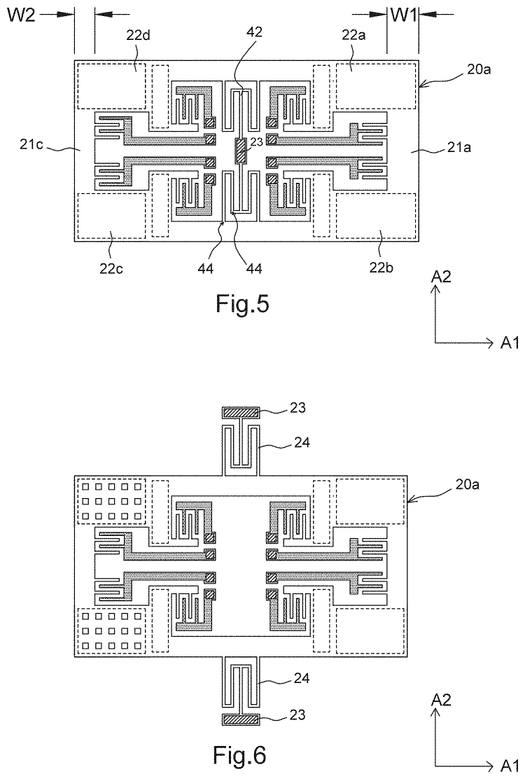

Refer to FIG. 5. The elastic element 24 includes a first arm 42 connected with the anchor point 24 and at least two second arms 44 connected to the interior of the frame structure of the movable mass block 20a, wherein the first arm 42 is the member interposed between and connected with the anchor point 23 and the second arm. As seen in FIG. 5, the first arm 42 is in form of a “T” shape, and the two second arms 44 are respectively disposed on two sides of the first arm 42, wherein most of the second arm 44 is parallel to the vertical portion of the “T” shape of the first arm 42. In the present invention, the shape of the elastic element can provide three degrees of freedom in three directions. Further, the elastic element can bend to increase the length of the arm and vary the width and size to adjust the sensitivity of the accelerometer and tolerate greater external impact. It is easily understood: the positions of the first-axis movable electrode elements 311a-311d and the second-axis movable electrode elements 321a-321d may be varied according requirement. For example, in FIG. 3, the first-axis movable electrode elements 311a and 311d and the first-axis movable electrode elements 311b and 311c are respectively connected with the connection segments 21d and 21 b. Alternatively, the positions of the positions of the first-axis movable electrode elements 311a-311d and the second-axis movable electrode elements 321a-321d may be modified to that of the embodiment shown in FIG. 4.

Refer to FIG. 5. In one embodiment, the position of the anchor point 23 may be deviated from the geometrical center of the frame structure. For example, the width W1 of the connection segment 21a is larger than the width W2 of the connection segment 21c. In such a structure, the position of the anchor point 23 is deviated from the geometrical center of the frame structure, and the masses of the movable mass block 20a, which are respectively on two sides of the second axis A2, are different. It is easily understood: through-holes may be formed in the mass regions 22c and 22d in FIG. 5 to increase the difference of the masses of the mass regions of the movable mass block 20a, which are respectively distributed on two sides of the second axis A2.

In the embodiments described above, the anchor point 23 of the movable mass block 20a is disposed in the interior of the frame structure. However, the present invention is not limited by those embodiments. Refer to FIG. 6. In one embodiment, the anchor point 23 and the elastic element 24, which are for fixing the movable mass block 20a, are disposed in the exterior of the frame structure. It is easily understood: the movable mass block 20a a can still rotate with respect to a rotation axis A3 (such as the geometrical center of the frame structure). Therefore, the movable electrode elements and the stator electrode elements must be disposed symmetrically with respect to the rotation axis A3.

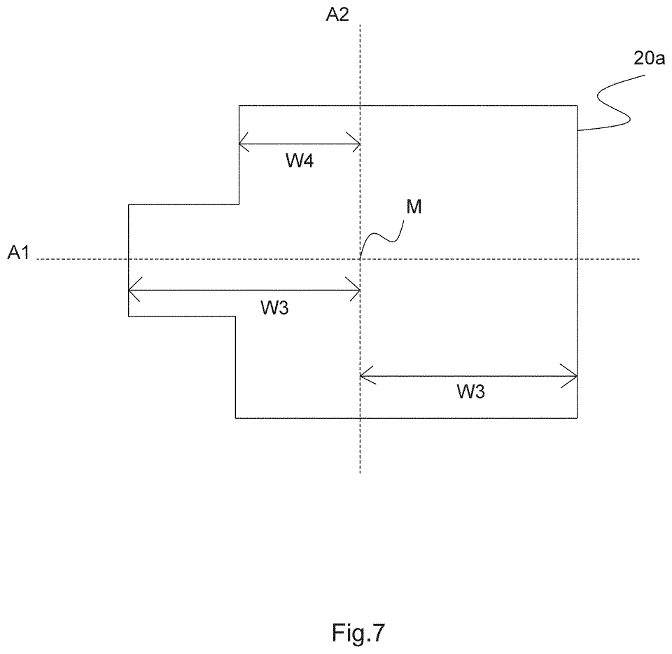

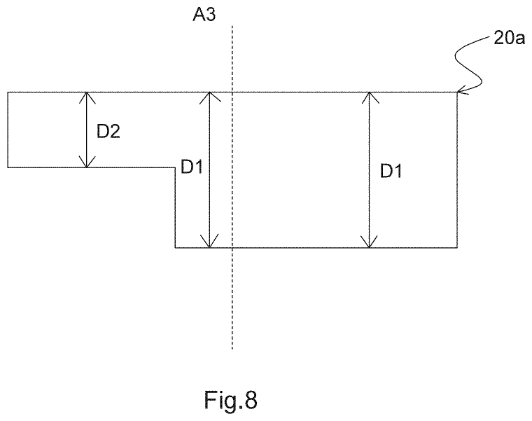

Refer to FIG. 7. The anchor point 23 of the movable mass block 20a is disposed at the middle point M of the greatest edge, which is distributed on two sides of the second axis A2. The middle point M is also the middle point of the movable mass block 20a with respect to the first axis A1. The width W3 of one side of the second axis A2 (parallel to the first axis A1) is a single value. The other side of the second axis A2 has two widths W3 and W4, wherein the width W4 is smaller than the width W3. In the embodiments described above, the thickness in the direction of the axis A3 is a single value. However, the present invention is not limited by those embodiments. In some embodiments, the thickness is designed to be non-uniform in an identical movable mass block 20a, so that the masses of the movable mass block 20a are different on two sides of the second axis A2. As shown in FIG. 8, the movable mass block 20a parallel to the plane defined by the first axis A1 and the second axis A2 has a rectangular shape, and the anchor point 23 is disposed at the intersection of the first axis A1 and the second axis A2, i.e. the geometrical center. The movable mass block 20a, which is on one side of the second axis A2, has a single thickness D1, the movable mass block 20a, which is on the other side of the second axis A2, has a thickness D1 and a thickness D2, wherein the thickness D2 is smaller than the thickness D1, whereby the movable mass block 20a has different masses on different sides.

While detecting the movement in one direction, the three-axis accelerometer of the present invention is less likely to be affected by the cross-talk from the other axes. Hence, the three-axis accelerometer of the present invention can detect the accelerations in the first axis, the second axis and the third axis more accurately and is exempted from the errors caused by the rotation of the movable mass block 20a. For considering both enhancing sensing sensitivity for a target axis and suppressing crosstalk on all other axes, various embodiments are provided as follows. Regarding sensing functions, “Ca” is a capacitance to be increased when the sensor is moving in a positive sensing direction for a target axis; and “Cb” is a capacitance to be decreased when the sensor is moving in the positive sensing direction for the target axis. Accordingly, provided that the three-axis accelerometer is moving in the positive direction of one sensing direction (target axis), a part which a moving comb structure gets closer to a stator comb structure has a capacitance “Ca”, and at the same time another part which a moving comb structure gets away from a stator comb structure has another capacitance “Cb”. For each sensing direction, the three-axis accelerometer of the present invention provides two differential sensing pairs, and each differential sensing pair includes one part with aforementioned “Ca” and another part with aforementioned “Cb”.

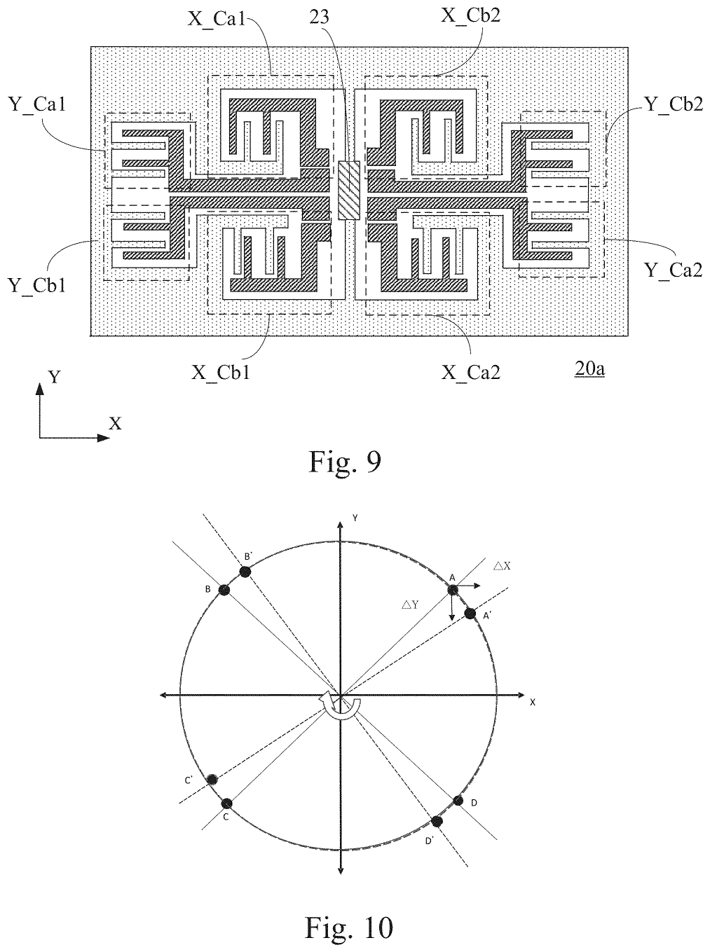

FIG. 9 is a top-view diagram of X-Y(A1-A2) plane illustrating the movable mass block 20a of sixth example according to the present invention. Referring FIG. 9, for a first X differential sensing pair which takes X axis as the sensing direction, one part with increasing capacitance and another part with decreasing capacitance are respectively marked as “X_Ca1” and “X_Cb1”, and a second X differential sensing pair has one part marked as “X_Ca2” with increasing capacitance and another part marked as “X_Cb2” with decreasing capacitance. Next, for structure arrangement, there may be divided into four quadrants on a X-Y plane with the anchor point 23 as an origin point where X_Ca1, X_Cb1, X_Ca2 and X_Cb2 are respectively positioned. It is noted that X_Ca1 and X_Ca2 are positioned in the two quadrants of a diagonal relationship, as well as X_Cb1 and X_Cb2. For example, X_Ca1 and X_Ca2 are allocated in a first diagonal relationship with respect to the anchor point 23. For performing sensing function, X_Ca1 and X_Ca2 are rotational symmetric to the third axis (Z axis), and the third axis is vertical to X-Y (A1-A2) plane. Similarly, for performing sensing function, X_Cb1 and X_Cb2 are rotational symmetric to the third axis, and the first X differential sensing pair and the second X differential sensing pair are also rotational symmetric to the third axis. For example, X_Cb1 and X_Cb2 are allocated in a second diagonal relationship with respect to the anchor point 23, and the first diagonal and the second diagonal are crossing at the anchor point 23.

Referring to FIG. 9 continuously, for a first Y differential sensing pair which takes Y axis as the sensing direction, one part with increasing capacitance and another part with decreasing capacitance are respectively marked as “Y_Ca1” and “Y_Cb1”, and a second Y differential sensing pair has one part marked as “Y_Ca2” with increasing capacitance and another part marked as “Y_Cb2” with decreasing capacitance. Next, for structure arrangement, there may be divided into four quadrants on a X-Y plane with the anchor point 23 as an origin point where Y_Ca1 Y_Cb1 Y_Ca2 and Y_Cb2 are respectively positioned. It is noted that Y_Ca1 and Y_Ca2 are positioned in the two quadrants of a diagonal relationship, as well as Y_Cb1 and Y_Cb2. For example, Y_Ca1 and Y_Ca2 are allocated in a third diagonal relationship with respect to the anchor point 23, and the first diagonal and the second diagonal are crossing at the anchor point 23. And, Y_Cb1 and Y_Cb2 are allocated in a fourth diagonal relationship with respect to the anchor point 23, and the third diagonal and the fourth diagonal are crossing at the anchor point 23. For performing sensing function, Y_Ca1 and Y_Ca2 are rotational symmetric to the third axis (Z axis), Y_Cb1 and Y_Cb2 are rotational symmetric to the third axis, and the first Y differential sensing pair and the second Y differential sensing pair are also rotational symmetric to the third axis.

Please refer both FIG. 9 and FIG. 1, for the first X differential sensing pair, the X_Ca1 part includes one sensing comb structure consisting of two movable electrode elements 311d and two fixing electrode elements 312d, and the part X_Cb1 includes another sensing comb structure consisting of two movable electrode elements 311c and two fixing electrode elements 312c. For the second X differential sensing pair, the X_Ca2 includes one comb structure consisting of two movable electrode elements 311b and two fixing electrode elements 312b, and the X_Cb2 includes another comb structure consisting of two movable electrode elements 311a and two fixing electrode elements 312a.

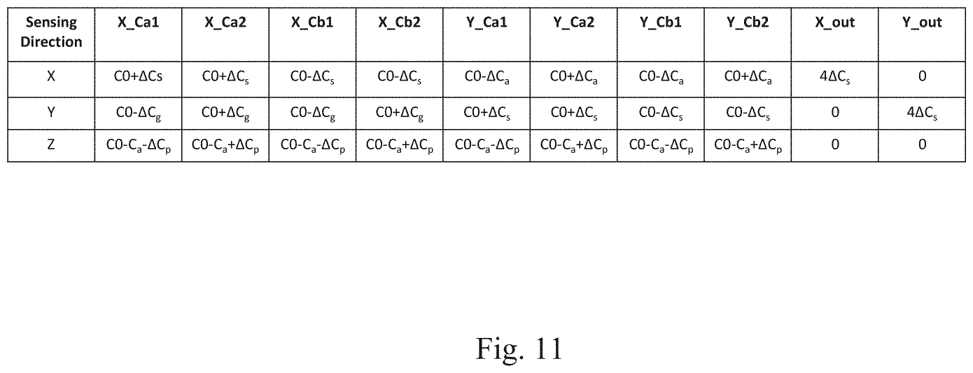

FIG. 10 is a schematic diagram illustrating position variation of movable X-axis sensing comb parts when exemplary movable mass block rotates clockwise during sensing acceleration rate of Y axis. FIG. 11 is a capacitance table illustrating measured capacitances in three different sensing directions as target axes performed by the three-axis accelerometer including one in FIG. 9. Please refer to FIG. 10, during sensing acceleration rate of Y axis, point A, B, C, D means the moving parts of the sensing comb structures for sensing X-axis direction. When the movable mass block rotates counterclockwise, points A, B, C, D will shift to the positions represented by A′, B′, C′ and D′, and the shifting variances are shown as delta X(ΔX) and delta Y(ΔY). Generally, when sensing Y-axis movement, there will be position variance on the moving parts for sensing X-axis direction, and such a position variance may generate unwanted capacitance change due to sensing capacitor gap change shown as FIG. 11. Shown in FIG. 11, C0 represents initial capacitance of a sensing comb structure without moving, and a capacitance to be measured is a sum of C0, parasitic capacitance and all capacitance change due to gap change by sensing motion or unwanted gap change, and comb overlap variation. In case that the three-axis accelerometer of the present invention is installed within a target object, ΔCₛ represents a capacitance change due to a gap change of electrode elements by the target acceleration; ΔC_{g} is a capacitance change due to unwanted gap change of electrode elements; ΔCₐ represents a capacitance change due to overlap area change of electrode elements; and ΔCₚ is a capacitance change due to distance between the second substrate and the first substrate change. Next, X_out means a capacitance sum of a capacitance (X_Ca1-X_Cb1) measured by the first X differential sensing pair and a capacitance (X_Ca2-X_Cb2) measured by the second X differential sensing pair. Y_out is a capacitance sum of a capacitance (Y_Ca1-Y_Cb1) measured by the first Y differential sensing pair and a capacitance (Y_Ca2-Y_Cb2) measured by the second Y differential sensing pair. The target object moves with 1G (G force) acceleration in the three sensing directions and the capacitances measured by the three-axis accelerometer are shown in FIG. 11. It is noted that there is no crosstalk in other axes when the capacitance is measured for the motion in a target sensing direction. Furthermore, refer to FIG. 10 and FIG. 11, when sensing the motion of Y axis, the capacitances corresponding to point A shifting point A′, point B shifting point B′, point C shifting point C′, and point D shifting point D′ are respectively measured as X_Cb2(=C0+ΔC_{g}), X_Ca1(=C0−ΔC_{g}), X_Cb1(=C0−ΔC_{g}), X_Ca2(=C0+ΔC_{g}) in where the item of “sensing direction” is “Y” in FIG. 11. Accordingly, during sensing Y-axis direction, X-out of zero means unwanted capacitance change may be cancelled under the design shown like FIG. 9.

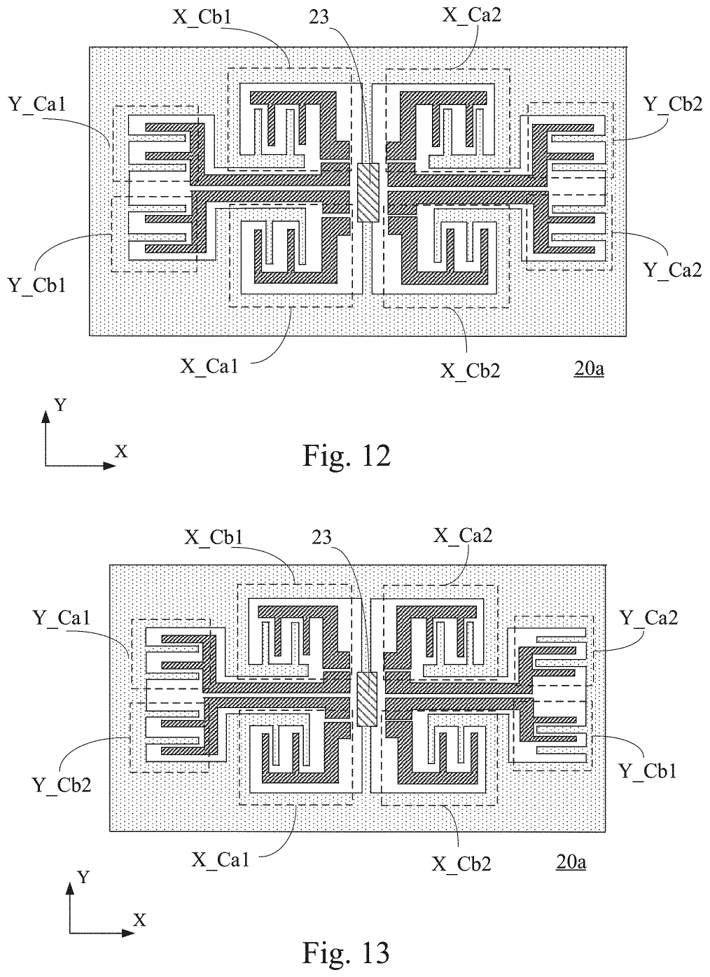

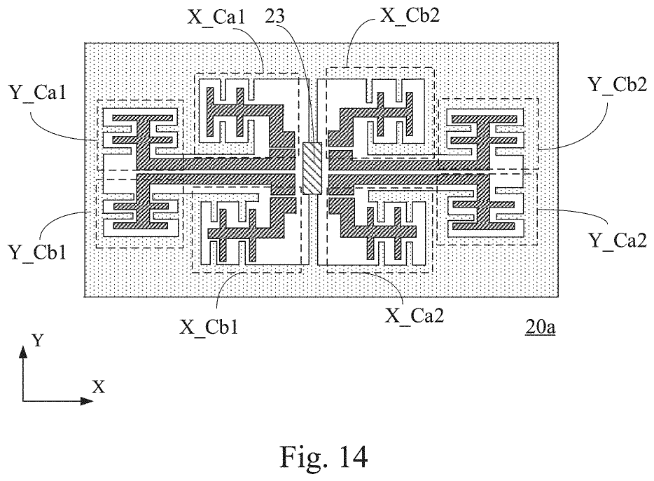

FIG. 12 and FIG. 13 are top-view diagrams of X-Y(A1−A2) planes respectively illustrating the movable mass block 20a of seventh and eighth examples according to the present invention. Similar as one shown in FIG. 9, for performing sensing function, X_Ca1 and X_Ca2 are rotational symmetric to the third axis, as well as X_Cb1 and X_Cb2; Y_Ca1 and Y_Ca2; and Y_Cb1 and Y_Cb2, where the third axis is vertical to X-Y (A1−A2) plane. Moreover, for performing sensing function, the first X differential sensing pair and the second X differential sensing pair are rotational symmetric to the third axis, and the first Y differential sensing pair and the second Y differential sensing pair are also rotational symmetric to the third axis. Next, similar as one shown in FIG. 9, each sensing comb structure consists two movable electrode elements and two fixing electrode elements. FIG. 14 is a top-view diagram of X-Y(A1−A2) plane illustrating the movable mass block 20a of ninth examples according to the present invention without repeating herein. Compared to ones in FIG. 9, FIG. 11, and FIG. 12, each sensing comb structure in FIG. 14 consists four movable electrode elements and four fixing electrode elements.

Accordingly, from the sixth example of FIG. 9 to the ninth example of FIG. 14, there are four differential sensing pairs for respective two sensing directions in total three sensing directions are rotational symmetric in 180 degrees rotation for performing sensing function. Referring to the third axis (Z axis) as a rotation axis in FIG. 9, the allocation (defined by sensing function) of the first X differential sensing pair is right corresponding to the allocation of second X differential sensing pair after rotation in 180 degrees. That is also to say, the allocation of the part with increasing capacitance of the first X differential sensing pair is right corresponding to the allocation of the part with increasing capacitance of the second X differential sensing pair after rotation in 180 degrees. Similarly, for performing sensing function, the allocation of the part with decreasing capacitance of the first X differential sensing pair is right corresponding to the allocation of the part with decreasing capacitance of the second X differential sensing pair after rotation in 180 degrees. The first Y and second Y differential sensing pairs have similar allocation as the first X and the second X ones, which are not repeatedly illustrated here.

In conclusion, the three-axis accelerometer of the present invention uses a single movable mass block to measure the accelerations in three axes and thus has a compact structure.

Further, the sensing capacitors, which are symmetrically disposed with respect the rotation axis for detecting accelerations in multiple directions, make the differential capacitance be zero, whereby the three-axis accelerometer of the present invention is exempted from the detection errors generated by the rotation of the movable mass block.

What is claimed is:

1. A three-axis accelerometer comprising:
a first substrate including a metal layer, wherein a portion of the metal layer is exposed from a surface of the first substrate to form a circuit pattern, wherein the surface is parallel to a two-dimensional plane defined by a first axis and a second axis, and a third axis is vertical to the surface, the first axis and the second axis;
a second substrate in form of a frame structure deposited on the first substrate, the second substrate including a movable mass block connected with the first substrate through an anchor point and an elastic element, the movable mass block able to move along the first axis parallel to the surface, rotate with respect to the third axis, and swing with respect to the second axis, wherein the movable mass block includes:
at least two third-axis movable electrode regions respectively disposed at two portions on two sides of the second axis; the two third-axis movable electrode regions form two third-axis sensing capacitors corresponding to the circuit pattern; the two third-axis sensing capacitors form a third-axis differential capacitor pair for detecting the displacement of the movable mass block in the third axis direction;
plural first-axis movable electrode elements connected to interior of the frame structure; and
plural second-axis movable electrode elements connected to the interior of the frame structure;
plural first-axis stator electrode elements electrically connected with the circuit pattern and disposed corresponding to the plural first-axis movable electrode elements, the plural first-axis stator electrode elements and the plural first-axis movable electrode elements forming plural first-axis sensing capacitors, wherein:
the plural first-axis sensing capacitors include two first-axis parts with increasing capacitances and two first-axis parts with decreasing capacitances when used to sense in the first axis direction due to capacitor gaps change;
for performing sensing function, the two first-axis parts with increasing capacitances are rotational symmetric to the third axis and allocated in a first diagonal relationship with respect to the anchor point; and
for performing sensing function, the two first-axis parts with decreasing capacitance are rotational symmetric to the third axis and allocated in a second diagonal relationship with respect to the anchor point, and the first diagonal and the second diagonal are crossing; and
plural second-axis stator electrode elements electrically connected with the circuit pattern and disposed corresponding to the plural second-axis movable electrode elements, the plural second-axis stator electrode elements and the plural second-axis movable electrode elements forming plural second-axis sensing capacitors, wherein:
the plural second-axis sensing capacitors include two second-axis parts with increasing capacitances and two second-axis parts with decreasing capacitances when used to sense in the second axis direction due to capacitor gaps change;
for performing sensing function, the two second-axis parts with increasing capacitances are rotational symmetric to the third axis and allocated in a third diagonal relationship with respect to the anchor point; and
for performing sensing function, the two second-axis parts with decreasing capacitance are rotational symmetric to the third axis and allocated in a fourth diagonal relationship with respect to the anchor point, and the third diagonal and the fourth diagonal are crossing.

2. The three-axis accelerometer according to claim 1, wherein at least two portions on two sides of the second axis respectively have different masses.

3. The three-axis accelerometer according to claim 1, wherein the movable mass block includes at least two mass regions disposed on two sides of the second axis; one of the mass regions has a plurality of through-holes or has a thickness smaller than a thickness of the mass region on the other side of the second axis.

4. The three-axis accelerometer according to claim 1, wherein the anchor point is disposed at interior of the frame structure.

5. The three-axis accelerometer according to claim 1, wherein the anchor point is disposed at a geometrical center of the frame structure.

6. The three-axis accelerometer according to claim 1, wherein the anchor point is deviated from a geometrical center of the frame structure.

7. The three-axis accelerometer according to claim 1, wherein the elastic element is connected with the anchor point through a single first arm.

8. The three-axis accelerometer according to claim 1, wherein the elastic element is connected with interior of the frame structure through at least two second arms.

9. The three-axis accelerometer according to claim 1, wherein the surface of the first substrate further includes a stop bump corresponding to the movable mass block.

10. The three-axis accelerometer according to claim 1 further comprising a cover cooperating with the first substrate to form a receiving room for receiving the second substrate.

11. The three-axis accelerometer according to claim 1, wherein the first substrate includes a complementary metal-oxide-semiconductor substrate.

12. The three-axis accelerometer according to claim 1, wherein the movable mass block includes monocrystalline silicon or doped low-resistance silicon.

13. The three-axis accelerometer according to claim 1, wherein a connection area of the anchor point and the first substrate includes an alloy, which includes at least one of aluminum, copper, germanium, indium, gold, and silicon.
